(19) United States
(12) Patent Application Publication
(10) Pub. No.: US 2016/0348243 A1
(43) Pub. Date: Dec. 1, 2016

(54) PROCESS FOR THE GENERATION OF THIN INORGANIC FILMS

(71) Applicant: BASF SE, Ludwigshafen (DE)

(72) Inventors: Ke XU, Witten (DE); Christian SCHILDKNECHT, Ludwigshafen (DE); Jan SPIELMANN, Mannheim (DE); Juergen FRANK, Ludwigshafen (DE); Florian BLASBERG, Frankfurt (DE); Daniel LOEFFLER, Birkenheide (DE); Martin GAERTNER, Worms (DE); Sabine WEIGUNY, Freinsheim (DE); Kerstin SCHIERLE-ARNDT, Zwingenberg (DE); Katharina FEDERSEL, Heidelberg (DE); Falko ABELS, Roemerberg (DE)

(73) Assignee: BASF SE, Ludwigshafen (DE)

(21) Appl. No.: 15/114,666

(22) PCT Filed: Jan. 22, 2015
(86) PCT No.: PCT/EP2015/051181

§ 371 Date: Jul. 27, 2016

(30) Foreign Application Priority Data
Jan. 27, 2014 (EP) 14152683.0

(51) Int. Cl. C23C 16/455; C07F 15/06; C07F 15/04; B01J 13/00; C07F 3/00

(52) U.S. Cl. CPC C23C 16/45553; B01J 13/0095; C07F 3/00; C07F 15/045; C07F 15/065

(57) ABSTRACT

The present invention relates to a process for the generation of thin inorganic films on substrates, in particular an atomic layer deposition process. This process comprises bringing a compound of general formula (I) into the gaseous or aerosol state and depositing the compound of general formula (I) from the gaseous or aerosol state onto a solid substrate, wherein R¹, R², R³, R⁴, R⁵, and R⁶ are independent of each other hydrogen, an alkyl group, or a trialkylsilyl group, n is an integer from 1 to 3, M is a metal or semimetal, 1 X is a ligand which coordinates M, and m is an integer from 0 to 4.

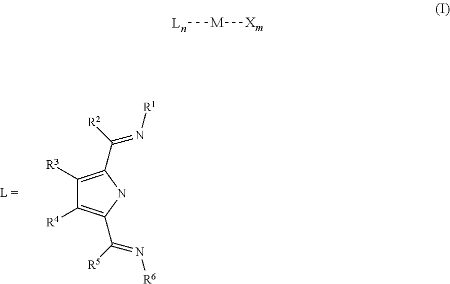

The present invention is in the field of processes for the generation of thin inorganic films on substrates, in particular atomic layer deposition processes.

With the ongoing miniaturization, e.g. in the semiconductor industry, the need for thin inorganic films on substrates increases while the requirements of the quality of such films become stricter. Thin inorganic films serve different purposes such as barrier layers, seeds, liners, dielectrica, or separation of fine structures. Several methods for the generation of thin inorganic films are known. One of them is the deposition of film forming compounds from the gaseous state on a substrate. In order to bring metal or semimetal atoms into the gaseous state at moderate temperatures, it is necessary to provide volatile precursors, e.g. by complexation the metals or semimetals with suitable ligands. These ligands need to be removed after deposition of the complexed metals or semimetals onto the substrate.

WO 2012/057 884 A1 discloses nitrogen-containing ligands for transition metals and their use in atomic layer deposition methods.

JP 2001 261 638 A discloses metal complex compounds which have a diimino pyrrolyl ligand useful as catalyst for an alpha olefin polymerization.

An object of the present invention was to provide a process for the generation of thin inorganic films on solid substrates by depositing metals or semimetals from the gaseous or aerosol state. It was desired that this process can be performed with as little decomposition of the precursor comprising the metal or semimetal as possible while the precursor is brought into the gaseous or aerosol state. At the same time it was desired to provide a process in which the precursor is easily decomposed after deposited on a solid substrate. A further object was to provide a process which is applicable for a broad variety of different metals or semimetals. It was also aimed at providing a process to generate high quality films under economically feasible conditions.

These objects were achieved by a process comprising bringing a compound of general formula (I) into the gaseous or aerosol state

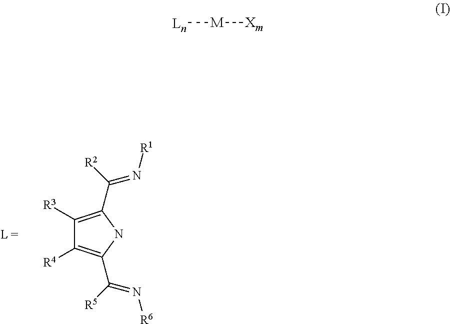

and depositing the compound of general formula (I) from the gaseous or aerosol state onto a solid substrate, wherein
R¹, R², R³, R⁴, R⁵, and R⁶ are independent of each other hydrogen, an alkyl group, or a trialkylsilyl group,
n is an integer from 1 to 3,
M is a metal or semimetal,
X is a ligand which coordinates M, and
m is an integer from 0 to 4.

The present invention also relates to a compound of general formula (I), wherein

R¹, R², R³, R⁴, R⁵, and R⁶ are independent of each other hydrogen, an alkyl group, or a trialkylsilyl group,
n is an integer from 1 to 3,

### M is Sr, Ba, Co, or Ni,

X is a ligand which coordinates M, and
m is an integer from 0 to 4.

The present invention also relates to the use of a compound of general formula (I), wherein

R¹, R², R³, R⁴, R⁵, and R⁶ are independent of each other hydrogen, an alkyl, or a trialkylsilyl group,
n is an integer from 1 to 3,
M is a metal or semimetal
X is a ligand which coordinates M, and
m is an integer from 0 to 4
for a film formation process on a solid substrate.

Preferred embodiments of the present invention can be found in the description and the claims. Combinations of different embodiments fall within the scope of the present invention.

In the process according to the present invention a compound of general formula (I) is brought into the gaseous or aerosol state. In the ligand L the two iminomethyl groups are conjugated to the pyrrole ring. It is believed that this renders L very stable against fragmentation such that it can be removed from the compound of general formula (I) without leaving undesired fragments e.g. in films formed by the process according to the present invention.

R¹, R², R³, R⁴, R⁵, and R⁶ are independent of each other hydrogen, an alkyl group, or a trialklylsilyl group. It is believed that the number of carbon atoms of ligand L influences the ease with which the compound of general formula (I) can be brought into the gaseous or aerosol state without significant decomposition. The absence of significant decomposition in the context of the present invention means that at least 90 wt.-% of the compound of general formula (I) can be brought into the gaseous or aerosol state without chemical change, more preferably at least 95 wt.-%, in particular at least 98 wt.-%.

Preferably, all alkyl and/or trialkylsilyl groups of the ligand L together contain up to twelve carbon atoms, more preferably up to eight. An alkyl group can be linear or branched. Examples for a linear alkyl group are methyl, ethyl, n-propyl, n-butyl, n-pentyl, n-hexyl, n-heptyl, n-octyl, n-nonyl, n-decyl. Examples for a branched alkyl group are iso-propyl, iso-butyl, sec-butyl, tert-butyl, 2-methyl-pentyl, 2-ethyl-hexyl, cyclopropyl, cyclohexyl, indanyl, norbornyl. A trialkylsilyl group can bear the same or different alkyl groups. Examples for a trialkylsilyl group with the same alkyl groups are trimethylsilyl, triethylsilyl, tri-n-propylsilyl, tri-iso-propylsilyl, tricyclohexylsilyl. Examples for a trialkylsilyl group with different alkyl groups are dimethyl-tert-butylsilyl, dimethylcyclohexylsilyl, methyl-di-iso-propylsilyl.

Preferably R¹ and R⁶ are according to the present invention independent of each other an alkyl or a trialkylsilyl group without a hydrogen atom connected to the carbon or silicone bond to the imino-nitrogen atom of ligand L. In this case the ligand L is believed to be more stable against rearrangement or cleavage at elevated temperatures, such as at more than 100° C., in particular at more than 150° C. Without being bound to this theory it is believed that this should generally lead to an increased thermal stability of the compound of general formula (I) at its vaporization temperature. A suitable method for determining the thermal stability is thermo gravimetry under an inert atmosphere as described in DIN 51006 (Thermische Analyse (TA)—Thermogravimetrie (TG)—Grundlagen, July 2006), wherein the more precise procedure A for the temperature control is preferred. If the compound of general formula (I) loses less than 10%, preferably less than 5% of its weight when heated to its vaporization temperature, it is considered to be thermally stable at this temperature. It is particularly preferred that R¹ and R⁶ are independent of each other tert-butyl or trimethylsilyl groups.

Preferably R³ and R⁴ are according to the present invention independent of each other hydrogen or a short alkyl group or a trimethylsilyl group. Examples for a short alkyl group are methyl, ethyl, n-propyl and iso-propyl. In this case, the complex is likely to become less bulky. It is more preferred that both R³ and R⁴ are hydrogen. The complex presumably packs even more efficiently if R² and R⁵ are independent of each other hydrogen, a short alkyl group, or a trimethylsilyl group. It is therefore preferred that R² and R⁵ are independent of each other hydrogen, a short alkyl group, or a trimethylsilyl group, such as in particular hydrogen, methyl, ethyl, n-propyl, iso-propyl, or trimethylsilyl. It is more preferred that R² and R⁵ are independent of each other hydrogen or methyl, it is more preferred that R² and R⁵ are both hydrogen. It is also more preferred that R² and R⁵ are both methyl. In this case, it is believed that the ligand L shows higher stability against fragmentation when heated to high temperatures such as more than 100° C., in particular to more than 150° C.

It is preferred that the molecular weight of the compound of general formula (I) is up to 1000 g/mol, more preferred up to 900 g/mol, even more preferred up to 800 g/mol, in particular up to 700 g/mol.

The compound of general formula (I) according to the present invention can contain from 1 to 3 ligands L, i.e. n is an integer from 1 to 3. Generally, the bigger the metal or semimetal M is the higher n can get. Usually, n is up to 3 only for large M. This is the case if M is a metal or semimetal from the fourth period or from higher periods of the periodic table of the elements. Preferably, n is from 1 to 2, more preferably n equals 2.

M in the compound of general formula (I) can be according to the present invention any metal or semimetal. Metals are Li, Be, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In Sn, Cs, Ba, La, Ce, Pr, Nd, Pm, Sm, Eu, Gd, Tb, Dy, Ho, Er, Tm, Yb, Lu, Hf, Ta, W, Re, Os Ir, Pt, Au, Hg, TI, Bi. Preferred metals are Ni, Co, Ta, Ru, Cu, Sr, and Ba. More preferred metals are Sr, Ba, Co, or Ni. Semimetals are B, Si, As, Ge, Sb.

The metal or semimetal M can be in any oxidation state. Preferably M is close to the oxidation state in which it is supposed to be in the final film on the solid substrate. For example, if a metal or semimetal film of oxidation state 0 is desired, the metal or semimetal M in the compound of general formula (I) should preferably be in the oxidation state 0 or −1 or +1 as long as a stable compound of general formula (I) is available. Otherwise the next higher or lower oxidation state is chosen with which a stable compound of general formula (I) can be obtains, such as −2 or +2. Furthermore, if a metal oxide film is desired in which the metal has the oxidation state +2, it is preferable that the metal or semimetal M in the compound of general formula (I) is in the oxidation state +1, +2, or +3. Another example is a metal oxide film in which the metal shall have the oxidation state +4. In this case, M in the compound of general formula (I) should preferable be in the oxidation state +4 or +3 or +5. More preferably, M in the compound of general formula (I) has the same oxidation state as it is supposed to be in the final film on the solid substrate. In this case no oxidation or reduction is necessary.

The ligand X in the compound of general formula (I) can be according to the present invention any ligand which coordinates M. If X bears a charge, m is normally chosen such that the compound of general formula (I) is neutrally charged. If more than one such ligand is present in the compound of general formula (I), i.e. m>1, they can be the same or different from each other. If m>2, it is possible that two ligands X are the same and the remaining X are different from these. X can be in any ligand sphere of the metal or semimetal M, e.g. in the inner ligand sphere, in the outer ligand sphere, or only loosely associated to M. Preferably, X is in the inner ligand sphere of M. It is believed that if all ligands X are in the inner ligand sphere of M the volatility of the compound of general formula (I) is high such that it can be brought into the gaseous or aerosol state without decomposition.

The ligand X in the compound of general formula (I) according to the present invention includes anions of halogens like fluoride, chloride, bromide or iodide and pseudohalogens like cyanide, isocyanide, cyanate, isocyanate, thiocyanate, isothiocyanate, or azide. Furthermore, X can be any amine ligand in which the coordinating nitrogen atom is either aliphatic like in dialkylamine, piperidine, morpholine, or hexamethyldisilazane; amino imides; aromatic like in pyrrole, indole, pyridine, or pyrazine. The nitrogen atom of the amine ligand is often deprotonated before coordinated to M. Furthermore, X can be an amide ligand such as formamide or acetamide; an amidinate ligand such as acetamidine; or a guanidinate ligand such guanidine. It is also possible that X is a ligand in which an oxygen atom coordinates to the metal or semimetal. Examples are alkanolates, tetrahydrofurane, acetylacetonate, acetyl acetone, 1,1,1,5,5,5-hexafluoroacetylacetonate, or 1,2-dimethoxyethane. Other suitable examples for X include both a nitrogen and an oxygen atom which both coordinate to M including dimethylamino-isopropanol. Also suitable for X are ligands which coordinate via a phosphorous atom to M. These include trialkyl phosphines such as trimethyl phosphine, tri-tert-butyl phosphine, tricyclohexyl phosphine, or aromatic phosphines such as triphenyl phosphine, or tritolylphosphine.

Further suitable ligands X are alkylanions like methyl, ethyl, propyl or butyl anions. X can also be an unsaturated hydrocarbon which coordinates with the π-bond to M. Unsaturated hydrocarbons include ethylene, propylene, iso-butylene, cyclohexene, cyclooctadiene, ethyne, propyne. Terminal alkynes can relatively easily be deprotonated. Then they can coordinate via the terminal carbon atom bearing the negative charge. X can also be an unsaturated anionic hydrocarbon which can coordinate both via the anion and the unsaturated bond such as allyl or 2-methyl-allyl. Cyclopentadienyl anions and substituted cyclopentadienyl anions are also suitable for X. Further suitable examples for X are carbonmonoxide (CO) or nitric oxide (NO). It is also possible to use molecules which contain multiple atoms which coordinate to M. Examples are bipyridine, o-terpyridine, ethylenediamine, substituted ethylenediamine, ethylene-di(bisphenylphosphine), ethylene-di(bis-tert-butylphosphine).

Small ligands which have a low vaporization temperature are preferred for X. These preferred ligands include carbonmonoxide, cyanide, ethylene, tetrahydrofurane, dimethylamine, trimethylphosphine, nitric oxide and 1,2-dimethoxyethane. Small anionic ligands which can easily be transformed into volatile neutral compounds upon protonation, for example by surface-bound protons, are preferred for X. Examples include methyl, ethyl, propyl, dimethylamide, diethylamide, allyl, 2-methyl-allyl.

Preferably, the compound of general formula (I) comprises two ligands L. In this case n equals 2. More preferably, there is no ligand X present in the compound of general formula (I), i.e. m equals 0. In this case the compound of general formula (I) becomes general formula (Ia):

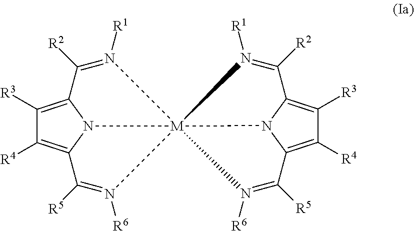

The two ligands L can either bear the same or different substituents for each R¹, R², R³, R⁴, R⁵, and R⁶. The same definitions for R¹, R², R³, R⁴, R⁵, and R⁶ apply as described above. Preferably, each R¹, R², R³, R⁴, R⁵, and R⁶ is the same substituent in both ligands L.

Due to the planarity of the ligand L, the compound of general formula (Ia) is chiral unless the substituents R¹, R², R³, R⁴, R⁵, and R⁶ are such that at least one of the ligands L has C₂ᵥ symmetry. This is, for example, the case if R¹ equals R⁶, R² equals R⁵, and R³ equals R⁴ which is generally preferred substitution pattern for the compound of general formula (I). If the compound of general formula (Ia) shows chirality, the compound can be used as racemic mixture or enantiomerically pure. The enantiomerically pure compounds of general formula (Ia) are preferred.

Some specific examples of the compound of general formula (I) are given in the table below.

| No. | R¹ | R² | R³ | R⁴ | R⁵ | R⁶ | n | M | X | m |
|---|---|---|---|---|---|---|---|---|---|---|
| C1 | tert- | H | H | H | H | tert- | 2 | Ba | — | 0 |
| | butyl | | | | | butyl | | | | |
| C2 | tert- | H | H | H | H | tert- | 2 | Sr | — | 0 |
| | butyl | | | | | butyl | | | | |
| C3 | iso- | H | H | H | H | iso- | 2 | Ba | — | 0 |
| | propyl | | | | | propyl | | | | |
| C4 | iso- | H | H | H | H | iso- | 2 | Sr | — | 0 |
| | propyl | | | | | propyl | | | | |
| C5 | n-butyl | H | H | H | H | n-butyl | 2 | Ba | — | 0 |
| C6 | n-butyl | H | H | H | H | n-butyl | 2 | Sr | — | 0 |
| C7 | iso- | H | H | H | H | iso- | 2 | Sr | — | 0 |
| | butyl | | | | | butyl | | | | |
| C8 | tert- | H | H | H | H | tert- | 2 | Ni | — | 0 |
| | butyl | | | | | butyl | | | | |
| C9 | tert- | H | H | H | H | tert- | 2 | Co | — | 0 |
| | butyl | | | | | butyl | | | | |
| C10 | tert- | H | Me | Me | H | tert- | 2 | Ba | — | 0 |
| | butyl | | | | | butyl | | | | |
| C11 | tert- | H | Me | Me | H | tert- | 2 | Sr | — | 0 |
| | butyl | | | | | butyl | | | | |
| C12 | tert- | Me | H | H | Me | tert- | 2 | Ba | — | 0 |
| | butyl | | | | | butyl | | | | |
| C13 | tert- | Me | H | H | Me | tert- | 2 | Sr | — | 0 |
| | butyl | | | | | butyl | | | | |
| C14 | TMS | H | H | H | H | TMS | 2 | Ba | — | 0 |
| C15 | TMS | H | H | H | H | TMS | 2 | Sr | — | 0 |
| C16 | TMS | Me | H | H | Me | TMS | 2 | Ba | — | 0 |
| C17 | TMS | Me | H | H | Me | TMS | 2 | Sr | — | 0 |
| C18 | tert- | Me | H | H | Me | TMS | 2 | Ba | — | 0 |
| | butyl | | | | | | | | | |
| C19 | tert- | H, | H, | H, | H, | tert- | 2 | Ba | — | 0 |
| | butyl, | Me | H | H | Me | butyl, | | | | |
| | TMS | | | | | TMS | | | | |
| C20 | tert- | H, | H, | H, | Me, | TMS, | 2 | Ba | — | 0 |
| | butyl, | H | H | H | H | TBDMS | | | | |
| | TBDMS | | | | | | | | | |
| C21 | TBDMS | H | H | H | H | TBDMS | 2 | Sn | — | 0 |
| C22 | TBDMS | Me | H | H | Me | TBDMS | 2 | Zn | — | 0 |
| C23 | tert- | Me | Me | Me | Me | tert- | 2 | Ba | — | 0 |
| | butyl | | | | | butyl | | | | |
| C24 | tert- | n- | Me | H | iso- | TBDMS | 2 | Sr | — | 0 |
| | butyl | butyl | | | propyl | | | | | |
| C25 | tert- | H | H | H | H | tert- | 3 | W | — | 0 |
| | butyl | | | | | butyl | | | | |
| C26 | tert- | H | H | H | H | tert- | 3 | Nd | — | 0 |
| | butyl | | | | | butyl | | | | |
| C27 | tert- | H | H | H | H | tert- | 1 | Na | — | 0 |
| | butyl | | | | | butyl | | | | |
| C28 | tert- | H | H | H | H | tert- | 1 | Fe | CO | 2 |
| | butyl | | | | | butyl | | | CN | 1 |
| C29 | TMS | H | H | H | H | TMS | 1 | Co | CO | 3 |
| C30 | tert- | Me | H | H | Me | tert- | 1 | Ni | CO | 2 |
| | butyl | | | | | butyl | | | Cl | 1 |
| C31 | tert- | Me | H | H | Me | tert- | 1 | Ni | ethene | 3 |
| | butyl | | | | | butyl | | | | |
| C32 | TMS | H | H | H | Me | tert- | 1 | Ag | CO | 3 |
| | | | | | | butyl | | | | |
| C33 | TMS | H | H | H | H | TMS | 2 | W | CO | 3 |
| C34 | tert- | Me | H | H | Me | tert- | 2 | Mo | CO | 3 |
| | butyl | | | | | butyl | | | | |
| C35 | TBDMS | H | H | H | H | TBDMS | 1 | Mn | CN | 2 |
| C36 | tert- | H | H | H | H | tert- | 1 | Cu | THF | 3 |
| | butyl | | | | | butyl | | | | |
| C37 | TMS | H | H | H | H | TMS | 1 | Ag | THF | 3 |
| C38 | tert- | H | H | H | H | tert- | 2 | Fe | THF | 2 |
| | butyl | | | | | butyl | | | | |
| C39 | TMS | H | H | H | H | TMS | 2 | Ru | bipy | 1 |
| C40 | TMS | H | H | H | H | TMS | 2 | Ru | CO | 2 |
| C41 | tert- | H | H | H | H | tert- | 1 | Fe | CN | 2 |
| | butyl | | | | | butyl | | | | |
| C42 | tert- | H | H | H | H | tert- | 2 | Ti | CN | 2 |
| | butyl | | | | | butyl | | | | |
| C43 | tert- | H | H | H | H | tert- | 1 | V | NMe₂ | 2 |
| | butyl | | | | | butyl | | | | |
| C44 | tert- | H | H | H | H | tert- | 2 | Ti | NMe₂ | 2 |
| | butyl | | | | | butyl | | | | |
| C45 | tert- | H | H | H | H | tert- | 2 | Ga | Cl | 1 |
| | butyl | | | | | butyl | | | | |
| C46 | tert- | Me | H | H | Me | tert- | 2 | Pt | PPh₃ | 2 |
| | butyl | | | | | butyl | | | | |
| C47 | tert- | H | H | H | H | tert- | 2 | Pd | PPh₃ | 2 |
| | butyl | | | | | butyl | | | | |
| C48 | TMS | H | Me | Me | H | TMS | 2 | Re | PPh₃ | 4 |
| C49 | tert- | H | H | H | H | tert- | 1 | Cu | PPh₃ | 1 |
| | butyl | | | | | butyl | | | | |
| C50 | tert- | H | H | H | H | tert- | 1 | Ag | NMe₂ | 1 |
| | butyl | | | | | butyl | | | | |
| C51 | tert- | H | H | H | H | tert- | 1 | Ta | n-BuO | 4 |
| | butyl | | | | | butyl | | | | |
| C52 | tert- | H | H | H | H | tert- | 1 | Cu | n-BuO | 1 |
| | butyl | | | | | butyl | | | | |
| C53 | tert- | H | H | H | H | tert- | 1 | Ni | allyl | 1 |
| | butyl | | | | | butyl | | | | |
| C54 | tert- | H | H | H | H | tert- | 1 | Co | allyl | 1 |
| | butyl | | | | | butyl | | | | |
| C55 | tert- | H | H | H | H | tert- | 1 | Ni | methyl- | 1 |
| | butyl | | | | | butyl | | | allyl | |
| C56 | tert- | H | H | H | H | tert- | 1 | Co | methyl- | 1 |
| | butyl | | | | | butyl | | | allyl | |

TMS stands for trimethylsilyl, TBDMS stands for tert-butyl-dimethylsilyl, THF stands for tetrahydrofurane, bipy stands for 2,2′-bipyridine, PPh₃ stands for triphenylphosphine, NMe₂ stands for dimethylamine, n-BuO stands for n-butoxy.

The compound of general formula (I) used in the process according to the present invention is used at high purity to achieve the best results. High purity means that the substance used contains at least 90 wt.-% compound of general formula (I), preferably at least 95 wt.-% compound of general formula (I), more preferably at least 98 wt.-% compound of general formula (I), in particular at least 99 wt.-% compound of general formula (I). The purity can be determined by elemental analysis according to DIN 51721 (Prufung fester Brennstoffe—Bestimmung des Gehaltes an Kohlenstoff and Wasserstoff—Verfahren nach Radmacher-Hoverath, August 2001). The ligand L in which R², R³, R⁴, R⁵ are hydrogen can be synthesized by condensation of 2,5-dicarbonylpyrrole with the respective amines under typical imine formation conditions. The precursor 2,5-dicarbonylpyrrole can be synthesized according to procedures of the following references:
K. Olsson, P. Pernemalm, Acta Chemica Scandinavica B 33 (1979), page 125-132
R. Miller, K. Olsson, Acta Chemica Scandinavica B 35 (1981) page 303-310

In the process according to the present invention the compound of general formula (I) is brought into the gaseous or aerosol state. This can be achieved by heating the compound of general formula (I) to elevated temperatures. In any case a temperature below the decomposition temperature of the compound of general formula (I) has to be chosen. Preferably, the heating temperature ranges from slightly above room temperature to 300° C., more preferably from 30° C. to 250° C., even more preferably from 40° C. to 200° C., in particular from 50° C. to 150° C.

Another way of bringing the compound of general formula (I) into the gaseous or aerosol state is direct liquid injection (DLI) as described for example in US 2009/0 226 612 A1. In this method the compound of general formula (I) is typically dissolved in a solvent and sprayed in a carrier gas or vacuum. Depending on the vapor pressure of the compound of general formula (I), the temperature and the pressure the compound of general formula (I) is either brought into the gaseous state or into the aerosol state. Various solvents can be used provided that the compound of general formula (I) shows sufficient solubility in that solvent such as at least 1 g/I, preferably at least 10 g/I, more preferably at least 100 g/I. Examples for these solvents are coordinating solvents such as tetrahydrofuran, dioxane, diethoxyethane, pyridine or non-coordinating solvents such as hexane, heptane, benzene, toluene, or xylene. Solvent mixtures are also suitable. The aerosol comprising the compound of general formula (I) should contain very fine liquid droplets or solid particles. Preferably, the liquid droplets or solid particles have a weight average diameter of not more than 500 nm, more preferably not more than 100 nm. The weight average diameter of liquid droplets or solid particles can be determined by dynamic light scattering as described in ISO 22412:2008. It is also possible that a part of the compound of general formula (I) is in the gaseous state and the rest is in the aerosol state, for example due to a limited vapor pressure of the compound of general formula (I) leading to partial evaporation of the compound of general formula (I) in the aerosol state.

It is preferred to bring the compound of general formula (I) into the gaseous or aerosol state at decreased pressure. In this way, the process can usually be performed at lower heating temperatures leading to decreased decomposition of the compound of general formula (I). It is also possible to use increased pressure to push the compound of general formula (I) in the gaseous or aerosol state towards the solid substrate. Pressures can range from 100 to 10⁻¹⁰ mbar, preferably from 1 to 10⁻⁸ mbar, more preferably from 0.01 to 10⁻⁶ mbar, in particular from 10⁻³ to 10⁻⁵ mbar such as 10⁻⁴ mbar. Preferably, however, the pressure is 10 bar to 10⁻⁷ mbar, more preferably 1 bar to 10⁻³ mbar, in particular 0.01 to 1 mbar, such as 0.1 mbar.

In the process according to the present invention a compound of general formula (I) is deposited on a solid substrate from the gaseous or aerosol state. The solid substrate can be any solid material. These include for example metals, semimetals, oxides, nitrides, and polymers. It is also possible that the substrate is a mixture of different materials. Examples for metals are aluminum, steel, zinc, and copper. Examples for semimetals are silicon, germanium, and gallium arsenide. Examples for oxides are silicon dioxide, titanium dioxide, and zinc oxide. Examples for nitrides are silicon nitride, aluminum nitride, titanium nitride, and gallium nitride. Examples for polymers are polyethylene terephthalate (PET), polyethylene naphthalene-dicarboxylic acid (PEN), and polyamides.

The solid substrate can have any shape. These include sheet plates, films, fibers, particles of various sizes, and substrates with trenches or other indentations. The solid substrate can be of any size. If the solid substrate has a particle shape, the size of particles can range from below 100 nm to several centimeters, preferably from 1 μm to 1 mm. In order to avoid particles or fibers to stick to each other while the compound of general formula (I) is deposited onto them, it is preferably to keep them in motion. This can, for example, be achieved by stirring, by rotating drums, or by fluidized bed techniques.

The deposition takes place if the substrate comes in contact with the compound of general formula (I). Generally, the deposition process can be conducted in two different ways: either the substrate is heated above or below the decomposition temperature of the compound of general formula (I). If the substrate is heated above the decomposition temperature of the compound of general formula (I), the compound of general formula (I) continuously decomposes on the surface of the solid substrate as long as more compound of general formula (I) in the gaseous or aerosol state reaches the surface of the solid substrate. This process is typically called chemical vapor deposition (CVD). Usually, an inorganic layer of homogeneous composition, e.g. the metal or the metal or semimetal oxide or nitride, is formed on the solid substrate as the organic material is desorbed from the metal or semimetal M. Typically the solid substrate is heated to a temperature in the range of 300 to 1000° C., preferably in the range of 350 to 600° C.

Alternatively, the substrate is below the decomposition temperature of the compound of general formula (I). Typically, the solid substrate is at a temperature lower than the temperature of the place where the compound of general formula (I) is brought into the gaseous or aerosol state, often at room temperature or only slightly above. Preferably, the temperature of the substrate is at least 30° C. lower than the place where the compound of general formula (I) is brought into the gaseous or aerosol state, more preferably at least 50° C. lower, in particular at least 100° C. lower. Alternatively, the solid substrate is at a temperature higher than the temperature of the place where the compound of general formula (I) is brought into the gaseous or aerosol state. Preferably, the temperature of the substrate is at least 30° C. lower than the decomposition temperature of the compound of general formula (I). Preferably, the temperature of the substrate is from room temperature to 400° C., more preferably from 100 to 300° C.

The deposition of compound of general formula (I) onto the solid substrate is either a physisorption or a chemisorption process. Preferably, the compound of general formula (I) is chemisorbed on the solid substrate. The chemisorption is typically accompanied by the loss of at least one of the ligands X or L. The loss of one of these ligands can be observed via infrared spectroscopy of the gas phase surrounding the solid substrate. One can determine if the compound of general formula (I) chemisorbs to the solid substrate by exposing a quartz microbalance with a quartz crystal having the surface of the substrate in question to the compound of general formula (I) in the gaseous or aerosol state. The mass increase is recorded by the eigen frequency of the quartz crystal. Upon evacuation of the chamber in which the quartz crystal is placed the mass should not decrease to the initial mass, but about a monolayer of the residual compound of general formula (I) remains if chemisorption has taken place. In most cases where chemisorption of the compound of general formula (I) to the solid substrate occurs, the x-ray photoelectron spectroscopy (XPS) signal (ISO 13424 EN—Surface chemical analysis—X-ray photoelectron spectroscopy—Reporting of results of thin-film analysis; October 2013) of M changes due to the bond formation to the substrate.

If the temperature of the substrate in the process according to the present invention is kept below the decomposition temperature of the compound of general formula (I), typically a monolayer is deposited on the solid substrate. Once a molecule of general formula (I) is deposited on the solid substrate further deposition on top of it usually becomes less likely. Thus, the deposition of the compound of general formula (I) on the solid substrate preferably represents a self-limiting process step. The typical layer thickness of a self-limiting deposition processes step is from 0.01 to 1 nm, preferably from 0.02 to 0.5 nm, more preferably from 0.03 to 0.4 nm, in particular from 0.05 to 0.2 nm. The layer thickness is typically measured by ellipsometry as described in PAS 1022 DE (Referenzverfahren zur Bestimmung von optischen and dielektrischen Materialeigenschaften sowie der Schichtdicke dünner Schichten mittels Ellipsometrie; February 2004).

Often it is desired to build up thicker layers than those just described. In order to achieve this in the process according to the present invention it is preferable to decompose the deposited compound of general formula (I) by removal of all L and X. Removing all L and X in the context of the present invention means that at least 95 wt.-% of the total weight of L and X in the deposited compound of general formula (I) are removed, preferably at least 98 wt.-%, in particular at least 99 wt.-%. The decomposition can be effected in various ways. The temperature of the solid substrate can be increased above the decomposition temperature.

Furthermore, it is possible to expose the deposited compound of general formula (I) to oxygen, ozone, a plasma like oxygen plasma, ammonia, oxidants like nitrous oxide or hydrogenperoxide, reductants like hydrogen, ammonia, alcohols, hydroazine, dialkylhydrazine or hydroxylamine; or solvents like water. It is preferable to use oxidants, plasma or water to obtain a layer of a metal oxide or a semimetal oxide. Exposure to water, an oxygen plasma or ozone is preferred. Exposure to water is particularly preferred. If layers of elemental metal or semimetal are desired it is preferable to use reductants. For layers of metal or semimetal nitrides it is preferable to use ammonia or hydrazine. Small molecules are believed to easily access the metal or semimetal M due to the planarity of the aromatic part of ligand L which is the consequence of the conjugation of the two iminomethyl groups to the pyrrole unit in ligand L. Typically, a low decomposition time and high purity of the generated film is observed.

A deposition process comprising a self-limiting process step and a subsequent self-limiting reaction is often referred to as atomic layer deposition (ALD). Equivalent expressions are molecular layer deposition (MLD) or atomic layer epitaxy (ALE). Hence, the process according to the present invention is preferably an ALD process.

A particular advantage of the process according to the present invention is that the compound of general formula (I) is very versatile, so the process parameters can be varied in a broad range. Therefore, the process according to the present invention includes both a CVD process as well as an ALD process.

After decomposition of the compound of general formula (I) deposited on the solid substrate, further compound of general formula (I) can be deposited on top to further increase the film thickness on the solid substrate. Preferably, the sequence of depositing the compound of general formula (I) onto a solid substrate and decomposing the deposited compound of general formula (I) is performed at least twice. This sequence can be repeated many times, for example 50 or 100 times. In this way films of a defined and uniform thickness are accessible. Typical films generated by repeating the above sequence have a thickness of 0.5 to 50 nm. It is possible to run each sequence with the same compound of general formula (I) or with different compounds of general formula (I) or with one or more compounds of general formula (I) and one or more metal or semimetal precursors different from general formula (I). For example, if the first, third, fifth and so on sequence is carried out with a compound of general formula (I) wherein M is Ba and every second, fourth, sixth and so on sequence is carried out with a Ti precursor, i.e. either a compound of general formula (I) or a different Ti comprising compound, it is possible to generate films of BaTiO₃.

Depending on the number of sequences of the process according to the present invention, films of various thicknesses are generated. Ideally, the thickness of the film is proportional to the number of sequences performed. However, in practice some deviations from proportionality are observed for the first 30 to 50 sequences. It is assumed that irregularities of the surface structure of the solid substrate cause this non-proportionality.

One sequence of the process according to the present invention can take from milliseconds to several minutes, preferably from 0.1 second to 1 minute, in particular from 1 to 10 seconds. The longer the solid substrate at a temperature below the decomposition temperature of the compound of general formula (I) is exposed to the compound of general formula (I) the more regular films formed with less defects.

The process according to the present invention is particularly suitable for the deposition of Ba, Sr, Co, or Ni on a solid substrate. Therefore, the present invention also relates to a compound of general formula (I), wherein

R¹, R², R³, R⁴, R⁵, and R⁶ are independent of each other hydrogen, an alkyl group, or a trialkylsilyl group,
n is an integer from 1 to 3,

### M is Sr, Ba, Co, or Ni,

X is a ligand which coordinates M, and
m is an integer from 0 to 4.

The same definitions for R¹, R², R³, R⁴, R⁵, R⁶, n, X, and m as described above apply. The compound of general formula (I) is generally stable enough such that it can be easily purified for example by sublimation and be obtained in high purity. High purity means that the substance used contains at least 90 wt.-% of compound of general formula (I), preferably at least 95 wt.-% of compound of general formula (I), more preferably at least 98 wt.-% of compound of general formula (I), in particular at least 99 wt.-% of compound of general formula (I). The purity can be determined by elemental analysis as described above.

The present invention also relates to the use of a compound of general formula (I), wherein

R¹, R², R³, R⁴, R⁵, and R⁶ are independent of each other hydrogen, an alkyl, or a trialkylsilyl group,
n is an integer from 1 to 3,
M is a metal or semimetal
X is a ligand which coordinates M, and
m is an integer from 0 to 4
for a film formation process on a solid substrate. The same definitions for R¹, R², R³, R⁴, R⁵, R⁶, n, X, and m as described above apply.

By the process according to the present invention a film is generated. A film can be only one monolayer of deposited compound of formula (I), several consecutively deposited and decomposed layers of the compound of general formula (I), or several different layers wherein at least one layer in the film was generated by using the compound of general formula (I). A film can contain defects like holes. These defects, however, generally constitute less than half of the surface area covered by the film. The film is preferably an inorganic film. In order to generate an inorganic film, all organic ligands L and X have to be removed from the film as described above. More preferably, the film is an inorganic film of a metal oxide, a semimetal oxide, a metal nitride, or a semimetal nitride. The film can have a thickness of 0.1 nm to 1 μm or above depending on the film formation process as described above. Preferably, the film has a thickness of 0.5 to 50 nm. The film preferably has a very uniform film thickness which means that the film thickness at different places on the substrate varies very little, usually less than 10%, preferably less than 5%. Furthermore, the film is preferably a conformal film on the surface of the substrate. Suitable methods to determine the film thickness and uniformity are XPS or ellipsometry.

The film generated by the present invention can be used for an electronic element comprising the film. The electronic element can have structural features of various sizes, for example from 100 nm to 100 μm. The process for forming the films for the electronic elements is particularly well suited for very fine structures. Therefore, electronic elements with sizes below 1 μm are preferred. Examples for electronic elements are field-effect transistors (FET), solar cells, light emitting diodes, sensors, or capacitors. In optical devices such as light emitting diodes or light sensors the film serves to increase the reflective index of the layer which reflects light. An example for a sensor is an oxygen sensor, in which a film can serve as oxygen conductor, for example if a metal oxide film is prepared. In field-effect transistors out of metal oxide semiconductor (MOS-FET) the film can act as dielectric layer or as diffusion barrier. It is also possible to make semiconductor layers out of films in which elemental nickel-silicon is deposited on a solid substrate. Furthermore, a cobalt-containing film, e.g. elemental cobalt, can be deposited by the process according to the present invention, for example as a diffusion barrier for copper-based contacts, such as Cu—W alloys.

Preferred electronic elements are capacitors. The film made by the process according to the present invention has several possible functions in capacitors. It can for example act as dielectric or as interlayer between dielectric layer and conductive layer to enhance lamination. Preferably the film acts as dielectric in a capacitor.

Further preferred electronic elements are complex arrays of integrated circuits. The film has several possible functions in complex integrated circuits. It can for example act as interconnect or as interlayer between a conducting copper layer and an insulating metal oxide layer to decrease copper migration into the insulating layer. Preferably the film acts as interconnect in a field-effect transistor or as interlayer in electrical contacts in complex integrated circuits.

### DESCRIPTION OF THE FIGURES

FIG. 1: Thermogravimetric analysis of compound C1, on the x-axis the temperature of the sample is given in ° C., on the y-axis the remaining mass as percentage of the initial mass of the sample is given.

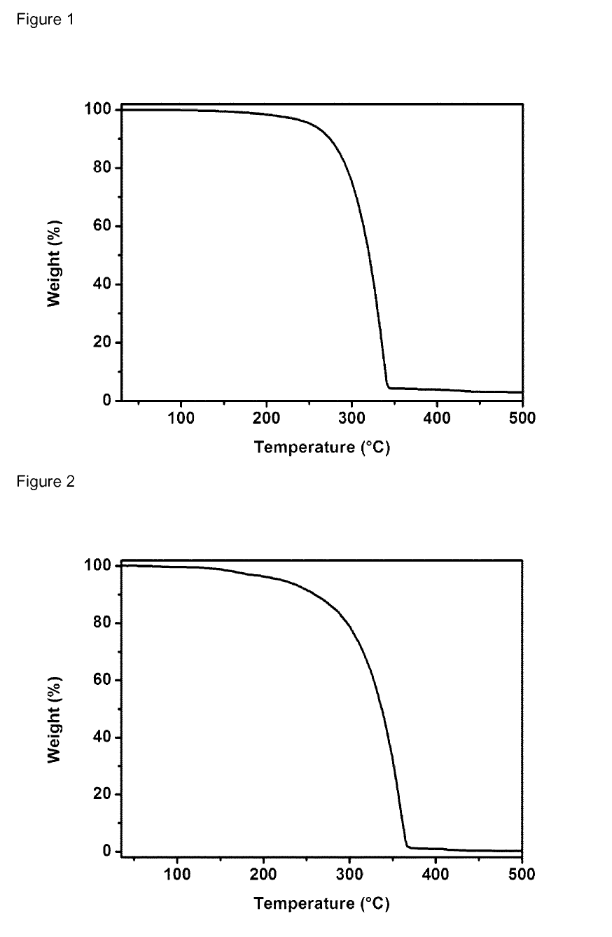

FIG. 2: Thermogravimetric analysis of compound C2, on the x-axis the temperature of the sample is given in ° C., on the y-axis the remaining mass as percentage of the initial mass of the sample is given.

### EXAMPLES

All synthetic steps involving the synthesis or handling of metal complexes were conducted under inert conditions using oven-dried glassware, dry solvents and an inert argon or nitrogen atmosphere.

### General Synthesis of Ligand L

0.14 moles of 2,5-diformylpyrrol, 3.5 moles of the corresponding amine and 150 ml of n-pentane were heated to reflux for 3.5 to 5 hours. Solvent and excess amine were removed by distillation, the residue was distilled at decreased pressure to yield the ligand L.

### General Synthesis of Compound of General Formula (I) for Examples 1 to 7

The ligand L (2 molar equivalents) was dissolved in hexane. NaH (2 molar equivalents), suspended in hexane, was added to ligand L. The reaction mixture was stirred at room temperature for 24 h. For the Sr-containing compounds SrI₂ (1 molar equivalent), for the Br-containing compounds BaI₂ (1 molar equivalent), dissolved in THF, was then added to the mixture comprising ligand L. This mixture was stirred for 48 h. After NaI separation, the solvent was removed under reduced pressure. The pure compound of general formula (I) was isolated by vacuum sublimation (150-200° C., 0.1 mbar).

The abbreviations in the hydrogen nuclear magnetic resonance (¹H-NMR) spectra have the conventional meaning: s for singlet, d for doublet, t for triplet, m for multiplet, bs for broad singlet.

### Example 1

### Compound C1 (bis(2,5-di-tert-butyliminopyrrole)barium) synthesized according to the general synthesis

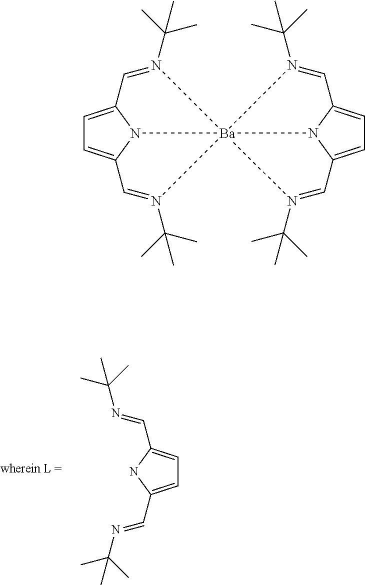

Analytics:

¹H-NMR (C₆D₆, 360 MHz, 25° C.): δ (in ppm) 8.08 s (1H), 6.65 s (1H), 1.09 s (9H)

Thermogravimetric analysis was performed with about 20 mg sample. It was heated by a rate of 5° C./min in an argon stream. The result of the thermogravimetric analysis is depicted in Figure

The mass spectrum obtained by an electron impact spectrometer (solid sample, 70 eV beam, MSD detector) has its most intense peak at 370 amu and a peak of 20% intensity at 602 amu.

### Example 2

### Compound C2 (bis(2,5-di-tert-butyliminopyrrole)strontium) synthesized according to the general synthesis

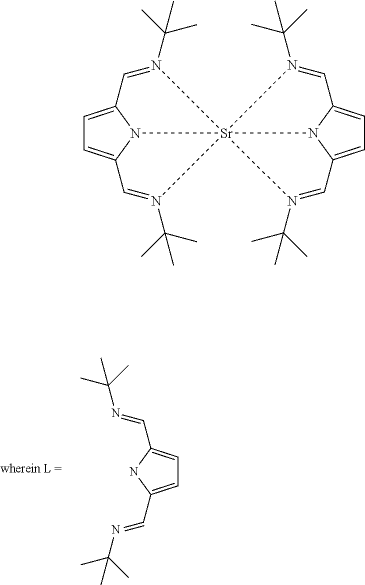

¹H-NMR (C₆D₆, 360 MHz, 25° C.): δ (in ppm) 7.89 s (1H), 6.37 s (1H), 1.11 s (9H)

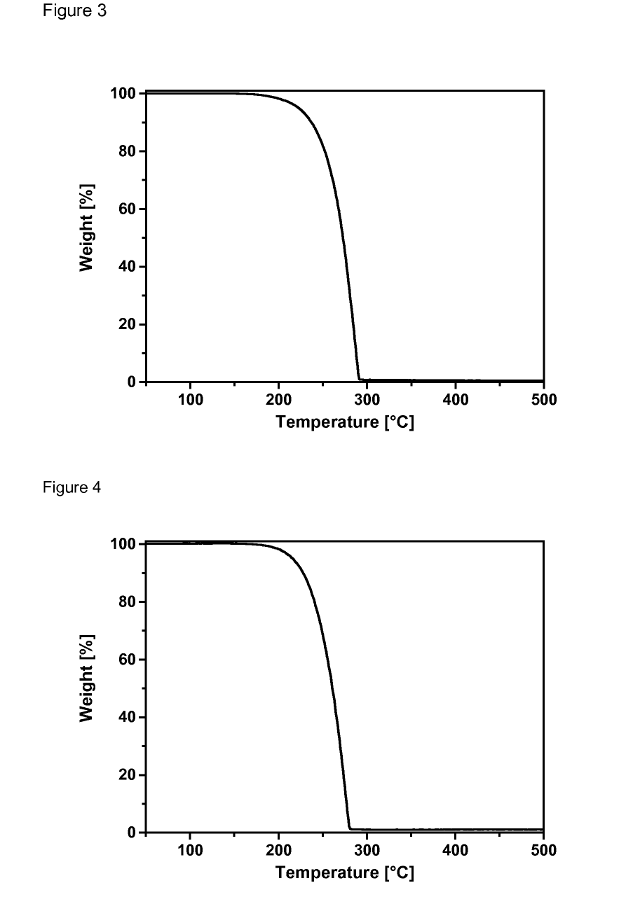

Thermogravimetric analysis was performed with about 20 mg sample. It was heated by a rate of 5° C./min in an argon stream. The result of the thermogravimetric analysis is depicted in FIG. 2.

The mass spectrum obtained by an electron impact spectrometer (solid sample, 70 eV beam, MSD detector) has its most intense peak at 552 amu and a peak of 70% intensity at 320 amu.

### Example 3

### Compound C3 (bis(2,5-di-iso-propyliminopyrrole)barium) synthesized according to the general synthesis

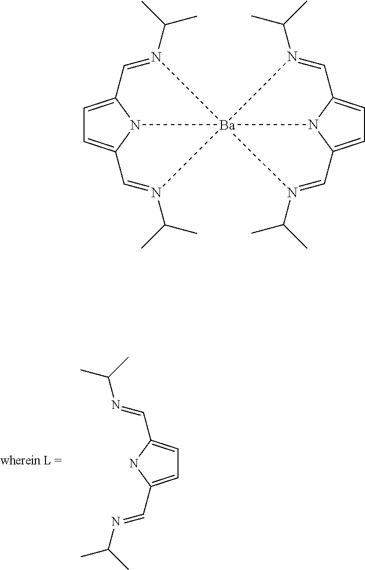

¹H-NMR (C₆D₆, 360 MHz, 25° C.): δ (in ppm) 7.92 s (1H), 6.73 s (1H), 3.08 m (1H), 0.87 d (6H)

### Example 4

### Compound C4 (bis(2,5-di-iso-propyliminopyrrole)strontium) synthesized according to the general synthesis

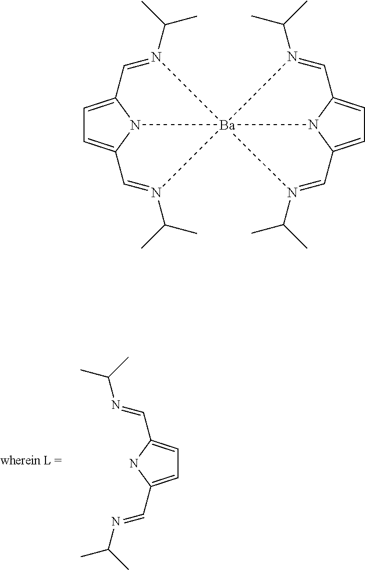

¹H-NMR (C₆D₆, 360 MHz, 25° C.): δ (in ppm) 7.95 s (1H), 6.75 s (1H), 3.07 m (1H), 0.89 d (6H)

### Example 5

### Compound C5 (bis(2,5-di-n-butyliminopyrrole)barium) synthesized according to the general synthesis

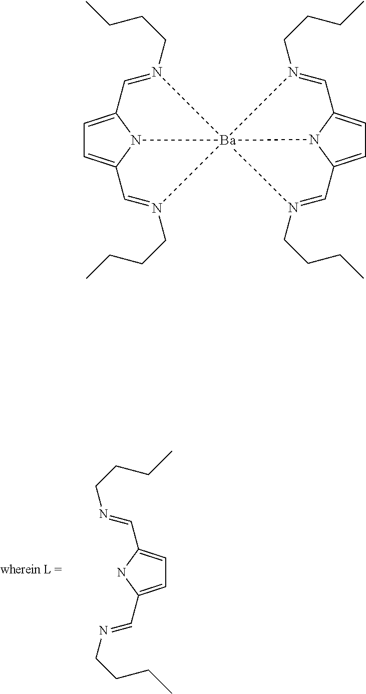

¹H-NMR (C₆D₆, 360 MHz, 25° C.): δ (in ppm) 7.89 s (1H), 6.76 s (1H), 3.04 t (2H), 1.31 m (2H), 1.14 m (2H), 1.11 t (3H)

### Example 6

### Compound C6 (bis(2,5-di-n-butyliminopyrrole)strontium) synthesized according to the general synthesis

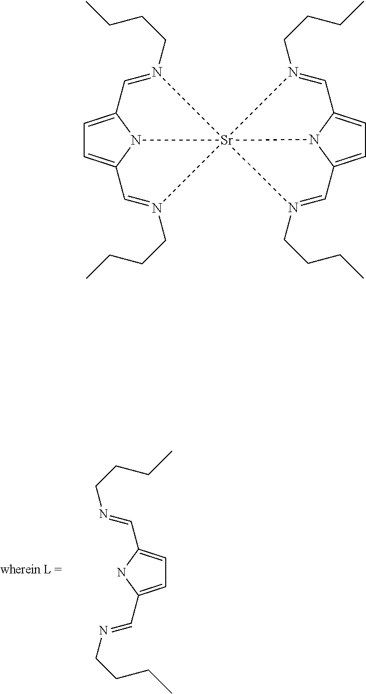

¹H-NMR (C₆D₆, 360 MHz, 25° C.): δ (in ppm) 7.90 s (1H), 6.72 s (1H), 3.01 t (2H), 1.30 m (2H), 1.13 m (2H), 0.81 t (3H)

### Example 7

### Compound C7 (bis(2,5-di-iso-butyliminopyrrole)strontium) synthesized according to the general synthesis

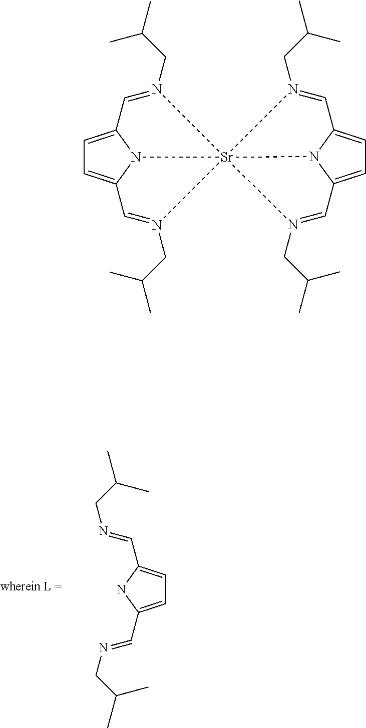

¹H-NMR (C₆D₆, 360 MHz, 25° C.): δ (in ppm) 7.83 s (1H), 6.74 s (1H), 2.85 d (2H), 1.51 m (1H), 0.74 d (6H)

### Example 8

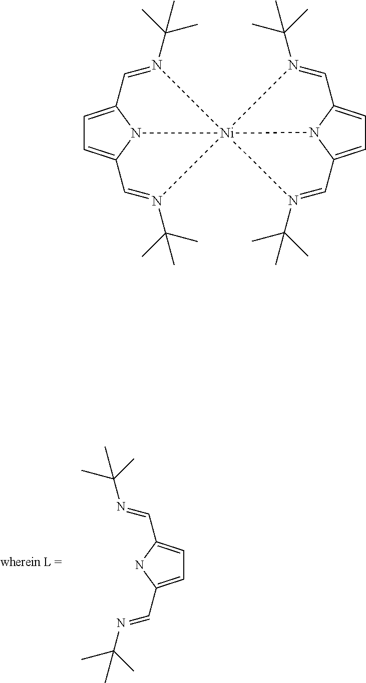

### Synthesis of compound C8 (bis(2,5-di-tert-butyliminopyrrole)nickel)

The ligand L (0.891 g, 3.82 mmol, 2 molar equivalents) was dissolved in 40 mL dry THF and added to a suspension of KH (0.230 g, 5.73 mmol, 3 molar equivalents) in 40 mL dry THF. The reaction mixture was stirred at room temperature for 18 h. In a separate flask, NiBr₂(dme) (0.608 g, 1.91 mmol, 1 molar equivalent) was suspended in 50 mL THF. The suspension containing the potassium salt of ligand L was filtered and the clear filtrate was added to the suspension comprising the metal salt. This mixture was stirred for 24 hrs at room temperature giving a dark brown solution with a colorless precipitate. After separation of the colorless potassium salt, the solvent was removed under reduced pressure. The solid brown residue was extracted with 80 mL toluene and solids were separated by filtration. The filtrate was again evaporated under reduced pressure giving 0.698 g of a solid crude product. The dark brown pure compound (0.465 mg, 66% yield) was isolated by vacuum sublimation (160-180° C., 0.4 mbar).

Elemental Analysis: found: C, 64.4; H, 9.2; N, 16.1; Ni, 10.6; Br, <0.05. calc: C, 64.3; H, 8.5; N, 16.1; Ni, 11.2; Br, 0.0.

LIFDI-MS from THF-solution: m/z=522 (100) amu (%), calc for M⁺=[C₂₈H₄₄N₆Ni]⁺: 522.3

Thermogravimetric analysis was performed with about 20 mg sample. It was heated by a rate of 5° C./min in an argon stream. The result of the thermogravimetric analysis is depicted in FIG. 3.

### Example 9

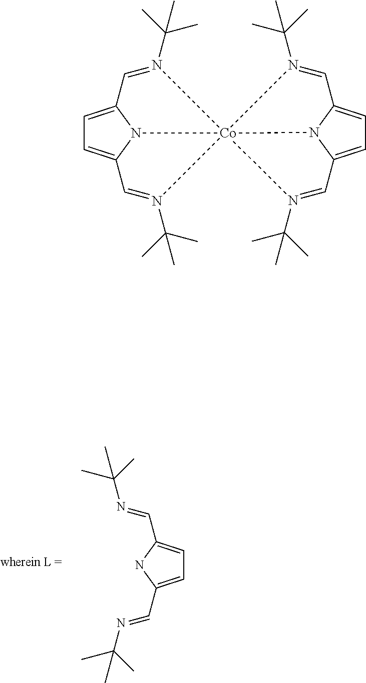

### Synthesis of compound C9 (bis(2,5-di-tert-butyliminopyrrole)cobalt)

The ligand L (0.891 g, 3.82 mmol, 2 molar equivalents) was dissolved in 40 mL dry THF and added to a suspension of KH (0.230 g, 5.73 mmol, 3 molar equivalents) in 40 mL dry THF. The reaction mixture was stirred at room temperature for 18 h. In a separate flask, CoCl₂ (0.248 g, 1.91 mmol, 1 molar equivalent) was suspended in 50 mL THF and stirred overnight at room temperature giving a deep blue mixture. The suspension containing the potassium salt of ligand L was filtered and the clear filtrate was added to the suspension comprising the metal salt. This mixture was stirred for 24 hrs at room temperature giving a dark red-brown solution with a colorless precipitate. After separation of the colorless potassium salt, the solvent was removed under reduced pressure. The solid brown residue was extracted with 100 mL toluene and solids were separated by filtration. The filtrate was again evaporated under reduced pressure giving 0.628 g of a solid crude product. The dark red colored pure compound (0.458 mg, 46% yield) was isolated by vacuum sublimation (160-170° C., 0.5 mbar).

Elemental Analysis: found: C, 64.4; H, 8.5; N, 15.9; Co, 10.5; Cl: <25 ppm. calc: C, 64.3; H, 8.5; N, 16.0; Co, 11.2; Cl, 0.0.

LIFDI-MS from THF-solution: m/z=523 (100) amu (%), calc for M⁺=[C₂₈H₄₄CoN₆]⁺: 523.3

Thermogravimetric analysis was performed with about 20 mg sample. It was heated by a rate of 5° C./min in an argon stream. The result of the thermogravimetric analysis is depicted in FIG. 4.

### Example 10

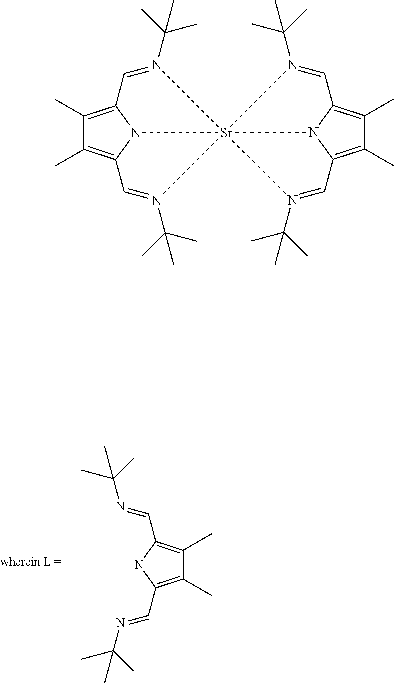

### Synthesis of compound C10 (bis(2,5-di-tert-butylimino-3,4-dimethyl-pyrrole)strontium)

The ligand L (1.0 g, 3.83 mmol, 2 molar equivalents) was dissolved in 20 mL dry THF and added to a suspension of KH (0.16 g, 4.02 mmol, 2.1 molar equivalents) in 30 mL dry THF. The reaction mixture was stirred at room temperature for 18 h. In a separate flask, SrI₂ (0.65 g, 1.91 mmol, 1 molar equivalent) was dissolved in 30 mL THF. The solution containing the potassium salt of ligand L was added to the solution comprising the strontium salt. This mixture was stirred for 24 hrs at room temperature giving a white suspension. After separation of the colorless potassium salt, the solvent was removed under reduced pressure. The pure compound (250 mg, 22% yield) was isolated by vacuum sublimation (160-180° C., 10⁻³ mbar).

¹H-NMR (THF-d₈, 500 MHz, 300 K): δ (in ppm) 8.23 s (2H), 2.09 s (6H), 1.12 s (18H).

LIFDI-MS from THF-solution: m/z=608 (55) [M⁺], 261 (100) [L⁺], calc for M⁺=[C₃₂H₅₂N₆Sr]⁺: 608.4

### Example 11

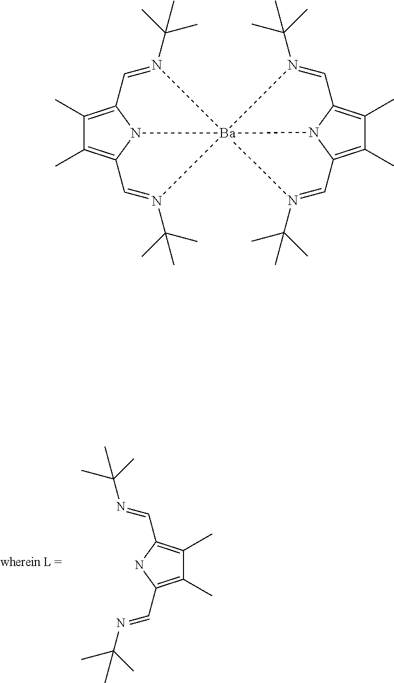

### Synthesis of compound C11 (bis(2,5-di-tert-butylimino-3,4-dimethyl-pyrrole)barium)

The ligand L (1.0 g, 3.83 mmol, 2 molar equivalents) was dissolved in 20 mL dry THF and added to a suspension of KH (0.16 g, 4.02 mmol, 2.1 molar equivalents) in 30 mL dry THF. The reaction mixture was stirred at room temperature for 16 h. In a separate flask, BaI₂ (0.75 g, 1.91 mmol, 1 molar equivalent) was dissolved in 30 mL THF. The solution containing the potassium salt of ligand L was added to the solution comprising the barium salt. This mixture was stirred for 18 h at room temperature giving a white suspension. After separation of the colorless potassium salt, the solvent was removed under reduced pressure. The residue was extracted with 20 mL n-hexane. A yellow compound crystallized at 8° C. overnight which was separated.

The pure compound (120 mg, 10% yield) was isolated by vacuum sublimation (180° C., 10⁻³ mbar).

¹H-NMR (THF-d₈, 360 MHz, 298 K): δ (in ppm) 8.22 s (2H), 2.07 s (6H), 1.13 s (18H).

LIFDI-MS from THF-solution: m/z=658 (53) [M+], 261 (100) [L+] amu (%), calc. for M⁺=[C₃₂H₅₂BaN₆]⁺: 658.1.

1: A process, comprising:
bringing a compound of general formula (I) into a gaseous or aerosol state 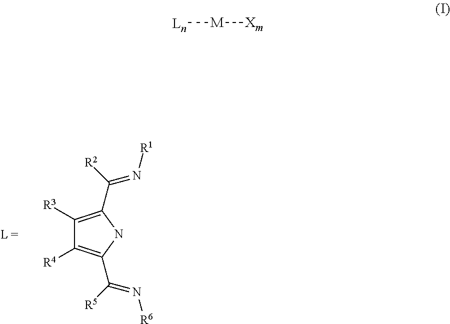
and
depositing the compound of general formula (I) from the gaseous or aerosol state onto a solid substrate, wherein
R¹, R², R³, R⁴, R⁵, and R⁶ are independent of each other and represent a hydrogen atom, an alkyl group, or a trialkylsilyl group,
n is an integer from 1 to 3,
M is a metal or semimetal,
X is a ligand which coordinates M, and
m is an integer from 0 to 4.

2: The process according to claim 1, wherein the compound of general formula (I) is chemisorbed on the surface of the solid substrate.

3: The process according to claim 1, further comprising:
decomposing the deposited compound of general formula (I) by removing all ligands L and X from the deposited compound of general formula (I).

4: The process according to claim 3, wherein said decomposing is carried out by exposing the deposited compound of general formula (I) to water, an oxygen plasma, or ozone.

5: The process according to claim 3, wherein
said depositing and decomposing are performed at least twice.

6: The process according to claim 1, wherein M is Sr, Ba, Ni or Co.

7: The process according to claim 1, wherein R² and R⁵ are independent of each other and represent a hydrogen atom or a methyl group.

8: A compound of general formula (I) 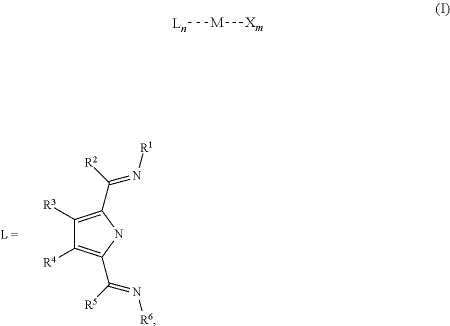
wherein
R¹, R², R³, R⁴, R⁵, and R⁶ are independent of each other and represent a hydrogen atom, an alkyl group, or a trialkylsilyl group,
n is an integer from 1 to 3,
M is Sr, Ba, Co, or Ni,
X is a ligand which coordinates M, and
m is an integer from 0 to 4.

9: The compound according to claim 8, wherein R³ and R⁴ represent a hydrogen atom.

10: The compound according to claim 8, wherein n is 2 and m is 0.

11: The compound according to claim 8, wherein R² and R⁵ are independent of each other and represent a hydrogen atom or a methyl group.

12. (canceled)

13: The process according to claim 3, further comprising:
upon said decomposing, forming an inorganic film on said solid substrate.
